(19) United States
(12) Patent Application Publication
(10) Pub. No.: US 2025/0351463 A1
(43) Pub. Date: Nov. 13, 2025

(54) THIN FILM TRANSISTOR AND PREPARATION METHOD THEREFOR, MEMORY, AND DISPLAY

(71) Applicant: INSTITUTE OF MICROELECTRONICS OF THE CHINESE ACADEMY OF SCIENCES, Beijing (CN)

(72) Inventors: Di GENG, Beijing (CN); Ling LI, Beijing (CN); Ming LIU, Beijing (CN); Xinlv DUAN, Beijing (CN); Congyan LU, Beijing (CN); Nianduan LU, Beijing (CN)

(73) Assignee: INSTITUTE OF MICROELECTRONICS OF THE CHINESE ACADEMY OF SCIENCES, Beijing (CN)

(21) Appl. No.: 18/873,243

(22) PCT Filed: Aug. 31, 2022
(86) PCT No.: PCT/CN2022/116071

§ 371 Date: Dec. 9, 2024

(30) Foreign Application Priority Data
Jun. 10, 2022 (CN) 202210657516.8

(51) Int. Cl. H10D 30/67; H10B 12/00; H10D 30/01; H10D 86/60

(52) U.S. Cl. CPC H10D 30/6757; H10B 12/00; H10D 30/0318; H10D 30/6706; H10D 30/6728; H10D 30/6731; H10D 30/6736; H10D 86/60

(57) ABSTRACT

A thin film transistor and a preparation method therefor, a memory, and a display. The thin film transistor comprises: a first source/drain layer (1), a first insulating layer (2), a second source/drain layer (3) and a second insulating layer (4) which are sequentially stacked; and a gate (6) and a channel layer (5) surrounding the gate (6), which are located in the second insulating layer (4), the second source/drain layer (3) and the first insulating layer (2). The channel layer (5) is in contact with the first source/drain layer (1), the first insulating layer (2), the second source/drain layer (3) and the second insulating layer (4). The thin film transistor is a CAA architecture of an annular channel surrounding the gate (6). Moreover, the leakage current of the gate (6) and the parasitic capacitance of the thin film transistor can be reduced by adding the second insulating layer (4) above the second source/drain layer (3).

### CROSS-REFERENCE TO RELATED PATENT APPLICATIONS

This application claims a priority from the Chinese Patent Application No. 202210657516.8, filed with the Chinese Patent Office on Jun. 10, 2022, entitled “THIN FILM TRANSISTOR AND PREPARATION METHOD THEREFOR, MEMORY, AND DISPLAY”, contents of which is incorporated herein by reference in its entirety.

### FIELD OF THE INVENTION

The disclosure relates to a thin film transistor, a preparation method therefor, a memory, and a display.

### BACKGROUND OF THE INVENTION

According to Moore's Law, integrated circuits continue to develop towards finer dimensions, and advanced fabrication process is one of the most cutting-edge nodes of integrated circuit fabrication. Currently, the advanced fabrication process has evolved to nodes of 5/7 nm, which places extremely high demands on further miniaturization of transistor.

The design of a Fin Field Effect Transistor (FinFET), which is one key architecture for the current transistor, can greatly improve circuit control and reduce leakage current, while greatly shortening the gate length of the transistor. However, the architecture of the FinFET is suitable for 10-22 nm process. For processes below 10 nm, such as 7 nm, 5 nm, and 3 nm, it will be limited by the scaling of FinFET width and cannot guarantee high performance and low power consumption while continuing to shrink in size. On the other hand, further improvement of the process results in a larger leakage current at the gate of the FinFET, and a reduced performance with more power consumption.

Therefore, it becomes an urgent problem to be solved how to further reduce the size of the transistor, improve performance of the transistor, reduce power consumption and reduce leakage current of the gate.

### SUMMARY OF THE INVENTION

According to the present disclosure, there is provided a thin film transistor and a method for preparing the same, a memory and a display, solving the technical problem of how to further reduce the size of the transistor, improve performance of the transistor, reduce power consumption and reduce leakage current of the gate.

In a first aspect, according to the present disclosure, there is provided a thin film transistor including:
a first source/drain layer, a first insulating layer, a second source/drain layer and a second insulating layer stacked in sequence; and a gate and a channel layer surrounding the gate, which are located within the second insulating layer, the second source/drain layer and the first insulating layer, in which the channel layer is in contact with the first source/drain layer, the first insulating layer, the second source/drain layer and the second insulating layer.

In a second aspect, according to the present disclosure, there is provided a method for preparing a thin film transistor including:
providing a substrate; forming in sequence a first source/drain layer, a first insulating layer, a second source/drain layer and a second insulating layer on the substrate; forming a hole extending to the first source/drain layer within the second insulating layer, the second source/drain layer and the first insulating layer; depositing a channel material on an inner wall of the hole and a surface of the second insulating layer to form a channel layer; and depositing a gate material on the channel layer to form a gate.

In a third aspect, according to the present disclosure, there is provided a memory including a plurality of storage arrays which include the thin film transistor according to the first aspect.

In a fourth aspect, according to the present disclosure, there is provided a display including a pixel circuit which includes the thin film transistor according to the first aspect.

According to the present disclosure, there is provided a thin film transistor, in which a gate of the thin film transistor passes through a second source/drain layer and a first insulating layer, and an annular channel surrounds the gate to form an architecture of Channel All Around, which is referred to as a transistor with CAA architecture. Compared with a transistor with FinFET architecture, the transistor with CAA architecture according to the present disclosure has the following advantages. Firstly, compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the first insulating layer, and the miniaturization of the channel length is not limited by the lithography process, which is conducive to achieve a smaller channel length, thereby increasing the channel width to length ratio, enabling greater device current and reducing power consumption. Secondly, the CAA architecture with the annular channel surrounding the gate can greatly increase the contact area between the gate and the channel, thereby significantly enhancing the control ability of the gate on the channel, and improving current conduction efficiency. Compared with a GAA (Gate All Around) architecture, the CAA architecture also has a larger contact area between the gate and channel. Thirdly, a second insulating layer is additionally arranged above the upper source/drain layer, i.e., the second source/drain layer. On one hand, the gate leakage current generated by overlapping of the gate and the second source/drain layer in the horizontal direction can be effectively reduced. On the other hand, the second insulating layer is beneficial to isolate the second source/drain layer from the metal layer of the subsequent process. Thus, the parasitic capacitance of the transistor is reduced.

The foregoing description is merely a summary of the technical solutions of the present disclosure. In order that the technical means of the present disclosure can be more clearly understood to be practiced in light of the description, and in order that the above and other objects, features and advantages of the present disclosure can be more clearly understood, the specific embodiments of the present disclosure are set forth as follows.

### BRIEF DESCRIPTION OF THE DRAWINGS

FIG. 1 is a schematic diagram of a thin film transistor according to an embodiment of the present disclosure;

FIG. 2 is a schematic diagram of a gate vertical portion, a gate horizontal portion, a channel vertical portion, and a channel horizontal portion according to an embodiment of the present disclosure;

FIG. 3 is a schematic diagram of a thin film transistor with a gate horizontal portion and a channel horizontal portion being removed according to an embodiment of the present disclosure;

FIG. 4 is a schematic flowchart of a method for preparing a thin film transistor according to an embodiment of the present disclosure; and

FIG. 5 is a schematic diagram of a storage array according to an embodiment of the present disclosure.

Reference signs are denoted as follows:

1. first source/drain layer; 2. first insulating layer; 3. second source/drain layer; 4. second insulating layer; 5. channel layer; 51. channel vertical portion; 52. channel horizontal portion; 6. gate; 61. gate vertical portion; 62. gate horizontal portion; 7. gate dielectric layer; 81. first thin film transistor; 82. second thin film transistor.

### DETAILED DESCRIPTION OF THE INVENTION

In order to enable those skilled in the art to understand the present disclosure more clearly, the technical solutions of the present disclosure will be described in detail through specific embodiments with reference to the accompanying drawings. Throughout the specification, unless otherwise specifically stated, the terms used herein are to be understood as having the meanings commonly used in the art. Thus, unless otherwise defined, all technical and scientific terms used herein have the same meaning as commonly understood by one of ordinary skill in the art to which this disclosure belongs. If there is a contradiction, the present specification preferably takes precedence. Unless otherwise specified, various devices and the like used in the present disclosure may be obtained through market purchase or may be prepared by existing methods.

In the description of the present disclosure, it should be noted that the orientation or position relationship indicated by the terms “center”, “upper”, “lower”, “left”, “right”, “vertical”, “horizontal”, “inner”, “outer” and the like is based on the orientation or position relationship shown in the accompanying drawings, or the orientation or position relationship normally placed when the product is used is merely for ease of description, rather than indicating or implying that the device or element referred to has to have a specific orientation, and is constructed and operated in a specific orientation, and therefore cannot be understood as a limitation to the present disclosure. In addition, the terms “first”, “second”, “third”, and the like are only used to distinguish descriptions, and cannot be understood as indicating or implying relative importance.

In addition, terms such as “horizontal”, “vertical”, and “overhang” do not indicate that a component is required to be absolutely horizontal or suspended, but may be slightly inclined. For example, “horizontal” means that the direction thereof is relatively horizontal relative to “vertical”, and does not indicate that the structure is necessarily completely horizontal, but may be slightly inclined.

Researches show that the reason why a large leakage current occurs in the gate of a transistor is as follows. In order to facilitate wiring, a gate of the transistor with vertical structure usually extends horizontally on an upper surface of an upper source/drain layer, and therefore the gate and the upper source/drain layer have an overlapping region in the horizontal direction. As the size of the transistor further shrinks, a significant leakage current will be generated between the gate and the upper source/drain layer in the overlapping region.

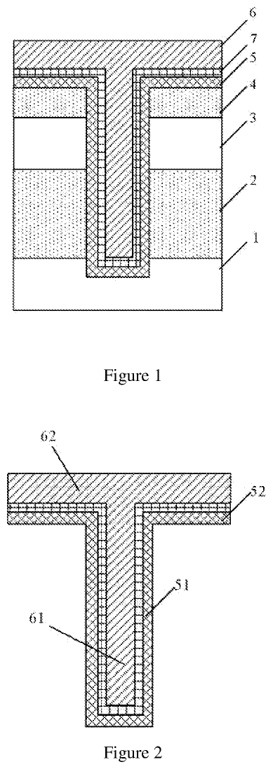

In a first aspect, according to the present disclosure, there is provided a Thin Film Transistor (TFT), whose structure is shown in FIG. 1, including:
a first source/drain layer 1, a first insulating layer 2, a second source/drain layer 3 and a second insulating layer stacked in sequence; and
a gate 6 and a channel layer 5 surrounding the gate 6, which are located within the second insulating layer 4, the second source/drain layer 3, and the first insulating layer 2, in which the channel layer 5 is in contact with the first source/drain layer 1, the first insulating layer 2, the second source/drain layer 3, and the second insulating layer 4.

Specifically, the TFT transistor provided in this embodiment has a vertical channel structure. For ease of understanding, the second source/drain layer 3 can be regarded as an upper source/drain of the TFT, and the first source/drain layer 1 can be regarded as a lower source/drain of the TFT. In actual use, the second source/drain layer 3 may be prepared as a source and the first source/drain layer 1 as a drain, or the second source/drain layer 3 may also be prepared as a drain and the first source/drain layer 1 as a source, which is not specifically limited herein.

The first insulating layer 2 is located between the second source/drain layer 3 and the first source/drain layer 1, and plays an insulating role.

The gate 6 is of a vertical gate structure, and the bottom of the gate 6 at least penetrates the second source/drain layer 3 and enters the first insulating layer 2. The bottom of the gate 6 can also penetrate the first insulating layer 2 and enter the first source/drain layer 1. The shape of the gate 6 may be cylindrical, and the cross-sectional shape of the gate 6 may be circular, elliptical or polygonal. The shape of the gate 6 may also be annular, and the cross-sectional shape of the gate 6 may be a circular ring, an elliptical ring, or a polygonal ring, which may be determined according to practical requirement. The optional materials for the gate 6 are Indium Tin Oxide (ITO), Indium Zinc Oxide (IZO), or Titanium Nitride (TiN).

The channel layer 5 is of a vertical channel structure, which is formed around the gate 6 within the second source/drain layer 3 and the first insulating layer 2. Therefore, the TFT transistor according to the present embodiment belongs to a CAA (Channel All Around) architecture in which an annular channel fully surrounds the gate 6. The cross-sectional shape of the channel layer 5 may be circular, elliptical or polygonal, and the cross-sectional shape of the channel layer 5 may be the same as or different from the cross-sectional shape of the gate 6.

A preferred shape of the channel layer 5 is a shape with the largest cross-sectional perimeter selected under the premise that the cross-sectional area of the channel layer 5 remains unchanged. In this way, the channel width of the channel layer 5 can be improved, thereby further improving the channel width-to-length ratio, and facilitating the improvement of the saturation current of the thin film transistor.

Materials for the channel layer 5 may be Indium Gallium Zinc Oxide (IGZO) or other metal oxide channel materials.

In some embodiments, the thin film transistor further includes a gate dielectric layer 7 located between the gate 6 and the channel layer 5. Optional material for the gate dielectric layer 7 includes at least one of hafnium oxide, hafnium aluminum oxide, and aluminum oxide.

In order to solve the problem that the current transistor is prone to generate a relatively large leakage current at the gate 6, in this embodiment, the second insulating layer 4 is formed on the upper surface of the second source/drain layer 3, which needs to be described in combination with two different processing manners.

In one processing manner, a structure of a TFT transistor including a second insulating layer 4 is shown in FIG. 2. The gate 6 includes a gate horizontal portion 62 and a gate vertical portion 61, and the channel layer 5 includes a channel vertical portion 51 and a channel horizontal portion 52. The channel vertical portion 51 surrounds the gate vertical portion 61. The channel vertical portion 51 is in contact with the first source/drain layer 1, the first insulating layer 2, the second source/drain layer 3 and the second insulating layer 4. The channel horizontal portion 52 is located between the gate horizontal portion 62 and the upper surface of the second insulating layer 4.

Specifically, the second insulating layer 4 is disposed between the second source/drain layer 3 and the horizontal extending portion of the gate 6 to reduce leakage current generated by the overlapping portion of the gate horizontal portion 62 and the second source/drain layer 3 in the horizontal direction. Since the second insulating layer 4 further increases the vertical distance of the overlapping region formed by the gate horizontal portion 62 and the second source/drain layer 3 in the horizontal direction, the parasitic capacitance between the gate 6 and the second source/drain layer 3 may also be reduced.

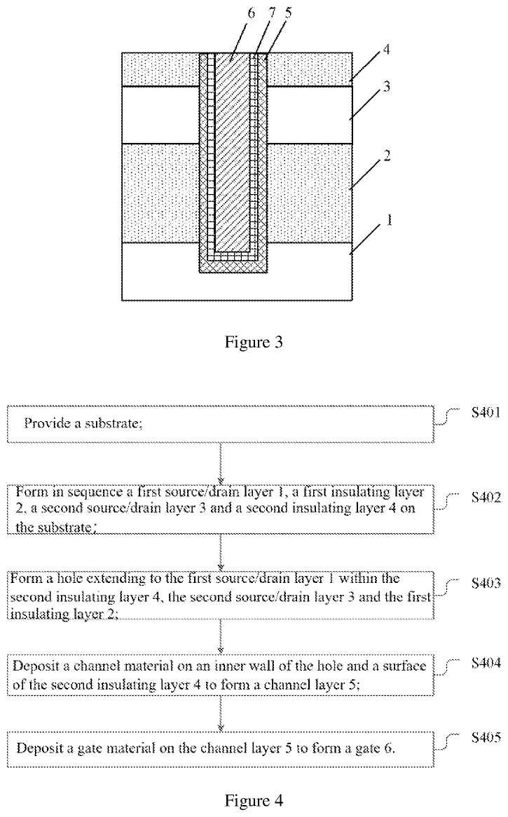

In another processing manner, a structure of a TFT transistor including a second insulating layer 4 is shown in FIG. 3, which differs from FIGS. 1 and 2 in that the tops of the gate 6 and the channel layer 5 are flush with the second insulating layer 4. The tops of the gate 6 and the channel layer 5 being flush with the second insulating layer 4 can either mean that the tops of the gate 6 and the channel layer 5 may be aligned with the upper surface of the second insulating layer 4, or that the height difference between the tops of the gate 6 and the channel layer 5 and the upper surface of the second insulating layer 4 does not exceed a set value, which is not specifically limited herein.

The TFT transistor of FIG. 3 removes the channel horizontal portion 52 and the gate horizontal portion 62, so that the tops of the gate 6 and the channel layer 5 are flush with the second insulating layer 4, and the gate 6 between different transistor devices can be isolated when the transistor is used to form a circuit. At the same time, removing the channel horizontal portion 52 and the gate horizontal portion 62 also avoids overlapping of the gate 6 and the first source/drain layer 1 in the horizontal direction, thereby reducing the parasitic capacitance and the leakage current of the gate 6.

The TFT transistor shown in FIG. 3 may be prepared directly. Alternatively, the transistor shown in FIG. 1 may be formed firstly, and then the channel horizontal portion 52 and the gate horizontal portion 62 are etched by grinding and polishing.

The material of the second insulating layer 4 can be a material with good insulation, such as silicon dioxide, which can significantly reduce the leakage current of the gate 6. In order to ensure insulating effect, the optional thickness of the second insulating layer 4 is 10-30 nm.

In general, the thin film transistor according to the present embodiment has the following characteristics.
1) Compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the insulating layer, and the miniaturization of the channel length is not limited by the lithography process, which is conducive to achieve a smaller channel length, thereby increasing the channel width to length ratio, enabling greater device current and reducing power consumption.
2) The CAA architecture with the annular channel surrounding the gate can greatly increase the contact area between the gate 6 and the channel layer 5, thereby significantly enhancing the control ability of the gate 6 on the channel layer 5, and improving current conduction efficiency. Compared with the GAA (Gate All Around) architecture, the CAA architecture also has a larger contact area between the gate 6 and the channel layer 5.
3) The second insulating layer 4 is added above the second source/drain layer 3. Firstly, leakage current of the gate 6 due to overlapping of the gate 6 and the second source/drain layer 3 in the horizontal direction can be reduced effectively. Secondly, the second insulating layer 4 increases the vertical distance of the overlapping region formed by the gate 6 and the second source/drain layer 3 in the horizontal direction, thereby reducing the parasitic capacitance between the gate 6 and the second source/drain layer 3. Thirdly, addition of the second insulating layer 4 is also beneficial to isolate the second source/drain layer 3 from the metal layer of the subsequent process, thereby reducing parasitic capacitance of the thin film transistor.
4) On the other hand, after removing portions of the gate 6 and the channel layer 5 above the second source/drain layer 3, overlap between the gate 6 and the first source/drain layer 1 in the horizontal direction can also be avoided, thereby reducing parasitic capacitance and leakage current of the gate 6.

In a second aspect, according to the present disclosure, there is provided a method for preparing a thin film transistor, as shown in FIG. 4, including steps S401 to S405 as follows.

S401: Provide a substrate, where a silicon substrate may be used.

S402: Form in sequence a first source/drain layer 1, a first insulating layer 2, a second source/drain layer 3 and a second insulating layer 4 on the substrate.

Specifically, a pre-oxidation layer may be deposited on the substrate with a thickness of 300-400 nm, followed by pre-cleaning, and then a metal material layer forming the first source/drain layer 1 may be deposited on the pre-oxidation layer as follows. The pre-oxidation layer is pre-cleaned, and the source/drain metal material is deposited on the pre-cleaned pre-oxidation layer. A double protective layer is then deposited on the source/drain metal material layer, which may be a double protective layer formed of SiN and SiO, and the thickness of the double protective layer is about 200 nm. Next, the source/drain metal material layer is photolithographically processed. In particular, after the double protective layer is covered with the photoresist, exposure, development, and etching are performed in sequence to form a first source/drain layer 1.

Next, a fill oxide layer is deposited on the first source/drain layer 1, followed by chemical mechanical polishing and cleaning, and after completion, an insulating layer material is deposited to form the first insulating layer 2.

Next, the steps for the first source/drain layer 1 are repeated on the first insulating layer 2 to deposit the second source/drain metal material, and then deposition of a double protective layer, photoresist covering, exposure, development, etching, and cleaning are performed in sequence to form a second source/drain layer 3.

Next, a fill oxide layer is deposited on the second source/drain layer 3, followed by chemical mechanical polishing and cleaning, and after completion, an insulating layer material is deposited to form the second insulating layer 4.

S403: Form a hole extending to the first source/drain layer 1 within the second insulating layer 4, the second source/drain layer 3 and the first insulating layer 2, where the required hole can be formed by deep etching as follows.

A through hole is formed as follows. A double protective layer (SiN+SiO) is deposited at the location where the through hole is to be formed, followed by covering of the photoresist, and then exposure, development, etching, cleaning and chemical mechanical polishing are performed, forming a through hole whose bottom reaches the first source/drain layer 1 and a through hole whose bottom reaches the second source/drain layer 3, respectively.

A channel hole is formed as follows. A double protective layer (SiN+SiO) is deposited at the location where the channel hole is to be formed, followed by covering of the photoresist. After aligning with the second source/drain layer 3, exposure, development, etching and cleaning are performed, forming a channel hole penetrating the second insulating layer 4, the second source/drain layer 3 and the first insulating layer 2, whose bottom reaches the first source/drain layer 1.

S404: Deposit a channel material on an inner wall of the hole and a surface of the second insulating layer 4 to form a channel layer 5.

S405: Deposit a gate material on the channel layer 5 to form a gate 6.

Specifically, the hole-forming method may be a deep hole etching. The method for depositing a channel material and a gate material within a channel hole may be atomic layer deposition.

In some embodiments, after the channel material is deposited, a gate dielectric material is deposited to form the gate dielectric layer 7, and then the gate material is deposited on a surface of the gate dielectric layer 7. The method for depositing the gate dielectric material may be atomic layer deposition.

In some embodiments, after forming the gate 6, the preparation method further includes the following steps.

Portions of the channel layer 5 and the gate 6 on an upper surface of the second insulating layer 4 are removed. The method for removing may be grinding, polishing and etching.

In a third aspect, according to the present disclosure, there is provided a memory including a plurality of storage arrays which include the thin film transistor according to the first aspect.

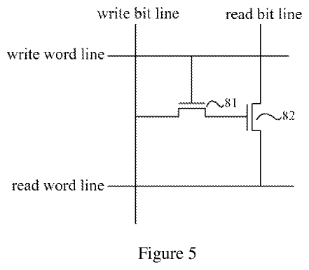

FIG. 5 shows an optional memory array structure of 2T0C in which one storage array includes two thin film transistors according to the embodiment of the present disclosure, i.e., a first thin film transistor 81 and a second thin film transistor 82.

Herein, the gate of the first thin film transistor 81 is electrically connected to a write word line (WWL), the source is electrically connected to a write bit line (WBL), and the drain is electrically connected to the gate of the second thin film transistor 82. The source of the second thin film transistor 82 is electrically connected to a read word line (RWL), and the drain is electrically connected to a read bit line (RBL).

By applying the thin film transistor according to the embodiment of the present disclosure to the memory circuit of 2T0C, the gate of one TFT transistor can be directly connected to the source/drain of another TFT transistor, without the need for external lead, and thus the volume of the entire memory can be greatly reduced to facilitate further miniaturization of the memory.

In addition, the thin film transistor according to the embodiment of the present disclosure may also be applied to memory arrays of 1T0C, 1T1C, and 2T1C, which are not specifically limited herein.

In a fourth aspect, according to the present disclosure, there is provided a display including a pixel circuit which includes the thin film transistor according to the first aspect.

According to one or more embodiments of the present disclosure, the present disclosure has the following beneficial effects or advantages.

According to the present disclosure, there is provided a thin film transistor and a method for preparing the same, a memory and a display. In the thin film transistor, a gate of the thin film transistor passes through a second source/drain layer and a first insulating layer, and an annular channel surrounds the gate to form an architecture of Channel All Around, which is referred to as a transistor with CAA architecture. Compared with a transistor with FinFET architecture, the transistor with CAA architecture according to the present disclosure has the following advantages. Firstly, compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the first insulating layer, and the miniaturization of the channel length is not limited by the lithography process, which is conducive to achieve a smaller channel length, thereby increasing the channel width to length ratio, enabling greater device current and reducing power consumption. Secondly, the CAA architecture with the annular channel surrounding the gate can greatly increase the contact area between the gate and the channel, thereby significantly enhancing the control ability of the gate on the channel, and improving current conduction efficiency. Compared with a GAA (Gate All Around) architecture, the CAA architecture also has a larger contact area between the gate and channel. Thirdly, a second insulating layer is additionally arranged above the upper source/drain layer, i.e., the second source/drain layer. On one hand, the gate leakage current generated by overlapping of the gate and the second source/drain layer in the horizontal direction can be effectively reduced. On the other hand, the second insulating layer is beneficial to isolate the second source/drain layer from the metal layer of the subsequent process. Thus, the parasitic capacitance of the transistor is reduced.

Although the preferred embodiments of the present disclosure have been described, those of ordinary skill in the art can make additional changes and modifications to these embodiments once they learn the basic inventive concept. Therefore, the appended claims are intended to be interpreted as including the preferred embodiments and all changes and modifications falling within the scope of the present disclosure.

Obviously, those skilled in the art can make various modifications and variations to the present disclosure without departing from the spirit and scope of the present disclosure. In this way, if these modifications and variations of the present disclosure fall within the scope of the claims of the present disclosure and their equivalent technologies, the present disclosure is also intended to include these modifications and variations.

1. A thin film transistor comprising:
a first source/drain layer, a first insulating layer, a second source/drain layer, and a second insulating layer stacked in sequence; and
a gate and a channel layer surrounding the gate, which are located within the second insulating layer, the second source/drain layer, and the first insulating layer, wherein the channel layer is in contact with the first source/drain layer, the first insulating layer, the second source/drain layer, and the second insulating layer.

2. The thin film transistor according to claim 1, wherein the gate comprises a gate vertical portion and a gate horizontal portion, and the channel layer comprises a channel vertical portion and a channel horizontal portion,
the channel vertical portion surrounds the gate vertical portion, and the channel vertical portion is in contact with the first source/drain layer, the first insulating layer, the second source/drain layer, and the second insulating layer, and
the channel horizontal portion is located between the gate horizontal portion and an upper surface of the second insulating layer.

3. The thin film transistor according to claim 1, wherein tops of the gate and the channel layer are flush with the second insulating layer.

4. The thin film transistor according to claim 1, wherein a thickness of the second insulating layer is 10 nm to 30 nm.

5. The thin film transistor according to claim 1, wherein the material for the second insulating layer is silicon dioxide.

6. The thin film transistor according to claim 1, further comprising a gate dielectric layer which is located between the gate and the channel layer.

7. A method for preparing a thin film transistor comprising:
providing a substrate;
forming in sequence a first source/drain layer, a first insulating layer, a second source/drain layer, and a second insulating layer on the substrate;
forming a hole extending to the first source/drain layer within the second insulating layer, the second source/drain layer and the first insulating layer;
depositing a channel material on an inner wall of the hole and a surface of the second insulating layer to form a channel layer; and
depositing a gate material on the channel layer to form a gate.

8. The method according to claim 7, wherein, after the gate is formed, the method further comprises:
removing portions of the channel layer and the gate located on an upper surface of the second insulating layer.

9. A memory comprising a plurality of storage arrays which comprise the thin film transistor according to claim 1.

10. A display comprising a pixel circuit which comprises the thin film transistor according to claim 1.
